(19) United States
(12) Patent Application Publication
(10) Pub. No.: US 2005/0127967 A1
(43) Pub. Date: Jun. 16, 2005

(54) Method and apparatus for controlling slew

(76) Inventor: Andrew R. Allen, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/732,682

(22) Filed: Dec. 10, 2003

(51) Int. Cl. H03K 5/12

(52) U.S. Cl. 327/170

(57) ABSTRACT

A method of controlling slew includes providing an output driver having a plurality of selectable variable impedances. Each selectable variable impedance is successively coupled to a pad of the output driver in response to initiation of a first signal transition to monotonically vary a driver source impedance throughout the signal transition.

### BACKGROUND

Integrated circuits frequently incorporate a bus or interface with a bus for communicating data, address, or control signals. Sharp transitions or changes in signals tend to generate undesirable high frequency components. The rise time or slew rate of a signal transmitted on the bus can be controlled in order to reduce signal ringing and interference.

Although the integrated circuit can be fabricated to provide a particular slew rate under certain operating conditions, these conditions are generally susceptible to changes in process, voltage, and temperature. In addition, although the integrated circuit may be designed to interface with an external bus having a nominal impedance, the actual impedance can vary significantly such that the integrated circuit does not provide the expected slew rate.

### SUMMARY

In view of limitations of known systems and methods, various methods and apparatus for controlling slew are described.

A method of controlling slew includes providing an output driver having a plurality of selectable variable impedances. Each selectable variable impedance is successively coupled to a pad of the output driver in response to initiation of a first signal transition to monotonically vary a driver source impedance throughout the signal transition.

A method of controlling slew includes providing a first signal to at least one delay line having a plurality of delay line taps, wherein each delay line tap provides a distinctly delayed version of the first signal. An impedance value for each of a plurality of selectable variable impedances is determined in accordance with a second signal. Each selectable variable impedance is associated with one of the delayed versions of the first signal. Each selectable variable impedance is selectively coupled to a common output pad in accordance with its associated delayed version of the first signal.

An output driver apparatus at least one delay line providing a plurality of delay line taps. Each tap provides a delayed version of any first signal received by the delay line. The output driver includes a pull-up portion comprising a first plurality of selectable variable impedances. Each selectable variable impedance of the first plurality is selectively coupled to a common output pad in accordance with an associated one of the delayed versions.

### BRIEF DESCRIPTION OF THE DRAWINGS

FIG. 1 illustrates one embodiment of a signal state transition.

FIG. 2 illustrates various embodiments of signal state transitions.

FIG. 3 illustrates one embodiment of a method of controlling slew.

FIG. 4 illustrates one embodiment of discretely, monotonically varying effective channel width.

FIG. 5 illustrates an alternative embodiment of discretely, monotonically varying effective channel width.

FIG. 6 illustrates one embodiment of a circuit for controlling an output driver slew.

FIG. 7A illustrates one embodiment of a pull-up portion of an output driver.

FIG. 7B illustrates one embodiment of a pull-down portion of an output driver.

FIG. 8 illustrates embodiments of selectable variable impedances associated with pull-up and pull-down portions of an output driver.

FIG. 9 illustrates one embodiment of a pull-up selectable variable impedance and a pull-down selectable variable impedance.

FIG. 10 illustrates one embodiment of a method of controlling slew.

FIG. 11 illustrates another embodiment of a method of controlling slew.

### DETAILED DESCRIPTION

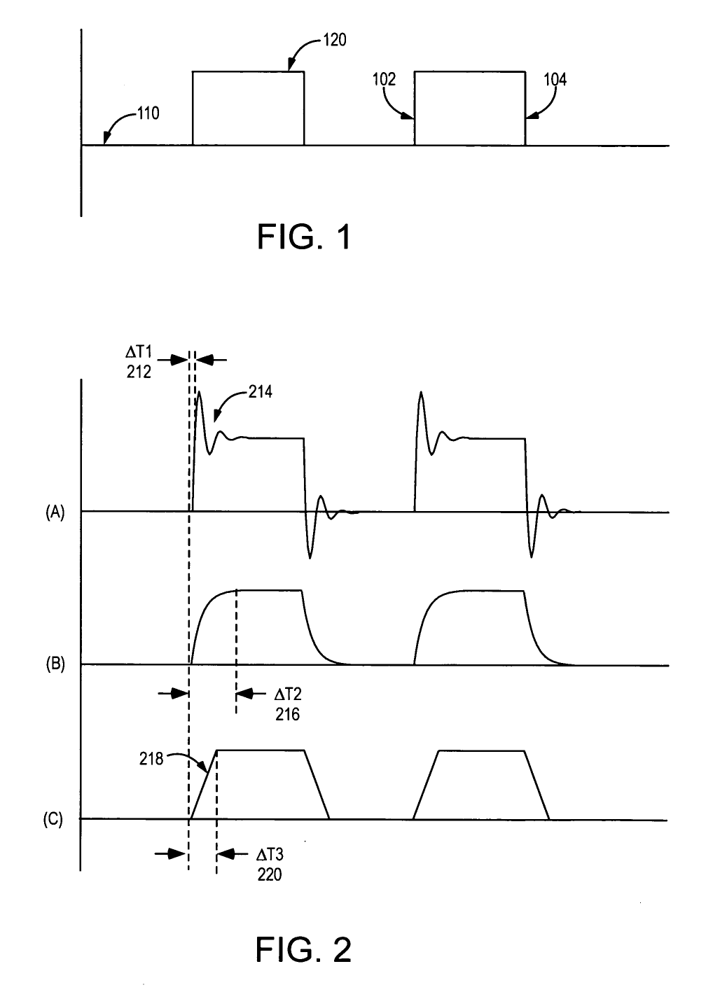

FIG. 1 illustrates one embodiment of an idealized state transition between a first state 110 and a second state 120 for signal 100 without any slew on either a rising edge 102 or falling edge 104. The idealized transition is a “step function” with an infinite slope for both the rising and falling edges. The high frequency components that would inevitably result from such a transition are undesirable in high speed bus architectures.

Referring to FIG. 2, the source impedance of the driver has a significant effect on transition time the driven signal. The source impedance may be chosen to result in a fast transition time ΔT1 (212) with an undesirable ringing 214 as illustrated by underdamped waveform 2(a). Pausing to allow settling of the signal inherently reduces the bus signaling bandwidth. Corruption of the communicated signal or other signals being communicated may occur if the ringing is ignored. Thus ringing can introduce erratic behavior.

Alternatively, the source impedance of the driver may be selected to avoid ringing at the cost of a longer transition time ΔT2 (216) as illustrated by overdamped waveform 2(b). Longer ringing times, however, also decrease the bus signaling bandwidth.

Although a driver may be designed to provide a fixed source impedance, such a design is optimal only for a pre-determined operating environment. Some prior art drivers provide for selecting an output impedance from at least two output impedances. This approach enables extending the operational range of the driver. However, such an approach does not account for process/voltage/temperature (PVT) variations.

The nominal slew rate is typically calculated as the difference between the first and second states (e.g., voltage difference) divided by the transition time. Instead of a fixed slew rate, however, the slew of a signal driven onto an output pad of an integrated circuit is controlled.

Integrated circuit impedances are typically realized using transistors. For metal oxide semiconductor field effect transistors (MOSFETs), resistance is proportional to length and inversely proportional to the width of the source-drain channel. The transistors may be coupled in series or parallel to achieve a greater effective channel length or width to alter the effective impedance.

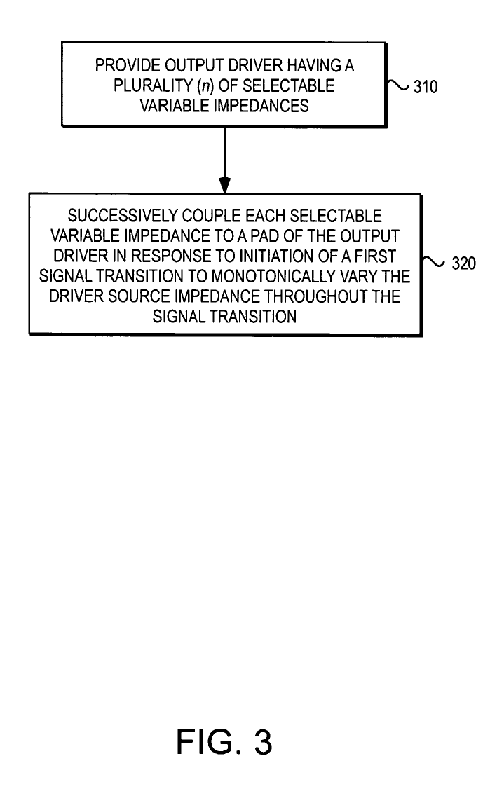

FIG. 3 illustrates one embodiment of a method for controlling slew. In step 310, an output driver having a plurality of selectable variable impedances is provided. Each variable impedance couples/de-couples the driver output to a reference voltage. Each variable impedance is successively coupled to (or de-coupled from) a pad of the output driver in response to initiation of a first signal transition to monotonically vary the driver source impedance throughout the signal transition in step 320. Typically the variable impedances couple the output pad to one of two reference voltage levels or power rails (e.g., ground, power supply) referred to as pull-up or pull-down voltages. A bus coupled to the output pad tends to be driven towards either the pull-up or the pull-down voltage in accordance with the value of the signal being driven.

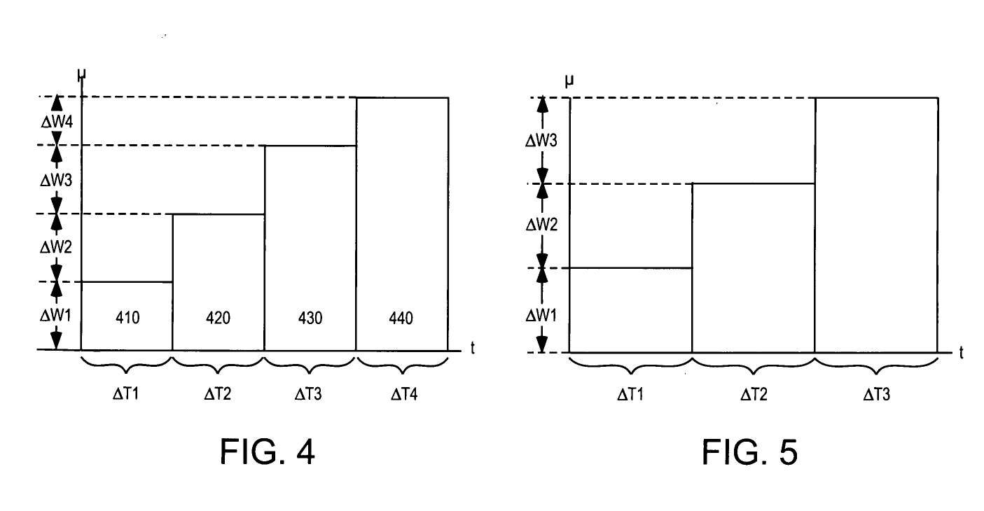

FIG. 4 illustrates one embodiment of discretely, monotonically varying an effective channel width. The channel width (and therefore the impedance) of the output driver is varied in a plurality (n=4) of steps. This may be accomplished, for example, by placing one or more additional transistors in parallel.

In the illustrated embodiment, the effective channel width monotonically increases from a pre-determined initial width throughout the state transition to a pre-determined final width in steps ΔW₁, ΔW₂, ΔW₃ . . . ΔWₘ, In an alternative embodiment, the effective channel width monotonically decreases throughout the state transition. Although the source impedance changes inversely to changes in channel width, the final effective width is selected to ensure that the resulting impedance substantially matches that of the bus being driven by the output driver.

In one embodiment, the change in channel width, ΔW, between steps is substantially the same such that ΔW₁≈ΔW₂, ΔW₃ . . . ΔWₙ. In the illustrated embodiment, although a plurality of the channel width steps are the same, at least one step is not the same as the others (e.g., ΔW₄≠ΔW₁, ΔW₂, ΔW₃). In one embodiment, the time intervals of the discrete steps are substantially the same such that ΔT₁, ΔT₂, ΔT₃, . . . ΔTₙ.

FIG. 5 illustrates another embodiment of discretely, monotonically varying the effective channel width. The effective channel width is varied in a plurality (n=3) of steps. In the illustrated embodiment, each channel-width step is substantially the same such that ΔW₁≈ΔW₂, ΔW₃. In one embodiment, the time intervals or durations of the discrete steps are substantially the same such that ΔT₁≈ΔT₂, ΔT₃.

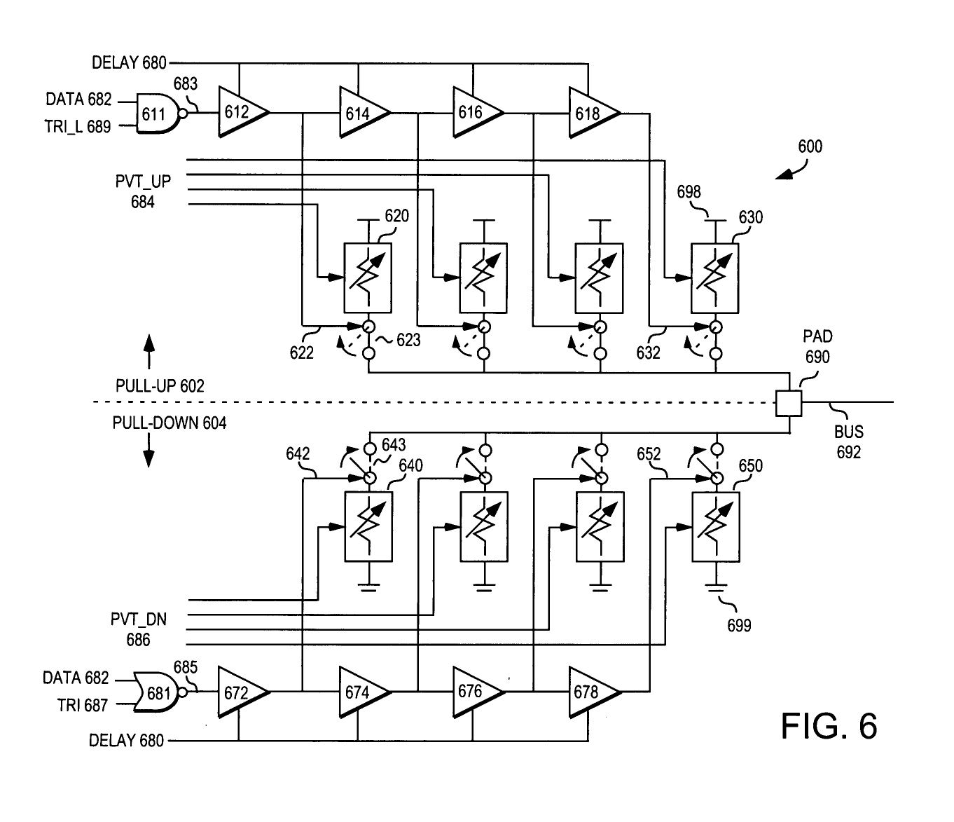

FIG. 6 illustrates one embodiment of an output driver circuit 600. An integrated circuit incorporating the output driver circuit 600 can be connected to an external bus 692 for distributing any driven signals at pad 690. The output driver includes a pull-up portion 602 and a pull-down portion 604 for driving the pad. The pull-up portion controls the slew of a rising edge of a data signal 682 being driven onto the pad. The pull-down portion controls the slew of a falling edge of the data signal 682 being driven onto the pad.

Each of the pull-up and pull-down portions includes an impedance network having a plurality of selectable variable impedances. The variable impedance of each group is set by a process/voltage/temperature (PVT) compensation signal. In particular, a PVT_UP 684 signal determines the value of variable impedances 620-630. A PVT_DN 686 signal determines the value of variable impedances 640-650.

Variable impedances 620-630, 640-650 may be selectively coupled to the output pad 690. In one embodiment, coupling of the variable impedances 620-630 to the output pad is controlled by a tapped delay line providing a plurality of delayed versions of the data signal 682. The pull-up delay line includes delay buffers 612, 614, 616, and 618. Similarly, the pull-down delay line includes delay buffers 672, 674, 676,678. In one embodiment, the amount of delay contributed by the pull-up and pull-down delay buffers is controlled by the same delay signal 680.

Each delay buffer contributes a delay to its received signal such that the individual delays are cumulative. Thus the delay lines provide a plurality of time shifted versions of the data signal. Delay line taps 622-632 and 642-652 enable routing the time-shifted versions to the selectable variable impedances 620-630 and 640-650.

In the illustrated embodiment, separate delay lines are provided for controlling the selection of the pull-up and the pull-down impedances. The buffers within each delay line are matched to ensure that the delay associated with each of delay taps 622-632 is the same as that of corresponding delay taps 642-652. In an alternative embodiment, the pull-up and pull-down portions share a common delay line and delay line taps.

Each variable impedance 620-630 within the pull-up portion is selectively coupled to the pad in accordance with its associated delay line tap 622-632. Similarly, each variable impedance 640-650 within the pull-down portion is selectively coupled to the pad in accordance with its associated delay line tap 642-652. Each pull-up variable impedance 620-630 has a corresponding pull-down variable impedance 640-650.

Combinatorial logic 611 and 681 are provided to permit operating the output driver in a “tri-state” mode. The tri-state signals TRI 687 and TRI_L are complementary signals. When in a tri-state mode, all of the pull-up and pull-down selectable impedances are de-coupled from the output pad.

The output driver may transition between the tri-state mode and either a first or a second logical state (e.g., “hi” or “low”). Alternatively, the output driver may transition between the first and second logical states.

When switching between the first state and the second state (neither state is the tri-state high impedance state) a pull-up variable impedance 620 is coupled to the pad when the corresponding pull-down variable impedance 640 is de-coupled from the pad. Similarly, when a pull-up variable impedance 620 is de-coupled from the pad, its corresponding pull-down variable impedance 640 is coupled to the pad.

When switching from the high impedance tri-state mode to either the first or second logical states, only either the pull-up or pull-down selectable variable impedances will be successively coupled to the output pad.

Coupling a pull-up variable impedance to the output pad tends to drive the pad towards the pull-up voltage 698. Similarly, coupling a pull-down variable impedance to the output pad tends to drive the pad towards the pull-down voltage 699. The bus 692 is thus driven towards one of two voltages in accordance with the signal being driven. These voltages or rails may be substantially the same levels powering the integrated circuit (e.g., typical integrated circuit V_{DD}, V_{SS}, where V_{SS} is signal ground). Alternatively, the rails may be associated with other supply levels.

From a small signal analysis, the output driver source impedance is substantially constant when switching between the first and second logical states. The coupling and de-coupling of the pull-up and pull-down impedances results in monotonically varying the large signal (i.e., DC) source impedance, but the small signal (i.e., AC) component is substantially the same because selectable variable impedances tied to one DC reference voltage are being “swapped” with a counterpart selectable variable impedance tied to ground. When switching between the tri-state mode and either of the first and second logical states, both the DC and AC source impedances vary monotonically as a result of the successive coupling of selectable variable impedances from only one of the pull-up or pull-down portions to the output pad.

In the illustrated embodiment, the pull-up variable impedances are selectively coupled in parallel to the output pad. Similarly, the pull-down variable impedances are selectively coupled in parallel to the output pad. Thus even if the amount of impedance for each variable impedance is substantially the same, the change in impedance contributed by the pull-up (or pull-down) variable impedance as the variable impedances are coupled/de-coupled is not a linear function. Thus the variable impedances may be selectively coupled to the output pad such that the resulting output pad impedance is a value other than the sum of the coupled impedances.

For example, assuming a nominal Z₀ for each selected variable impedance (m), the pull-up contribution to the output pad impedance varies inversely

$$( \frac{{Z}_{0}}{m} )$$

with the number of selected variable impedances such that the m pull-up impedances contribute

$$\frac{{Z}_{0}}{m}$$

to the output impedance.

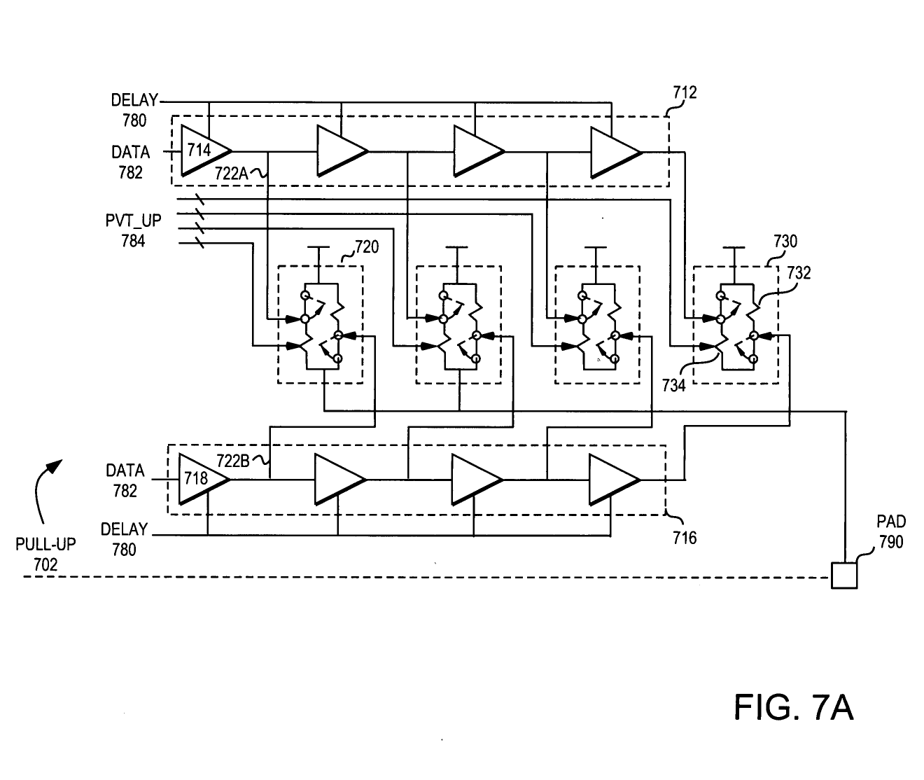

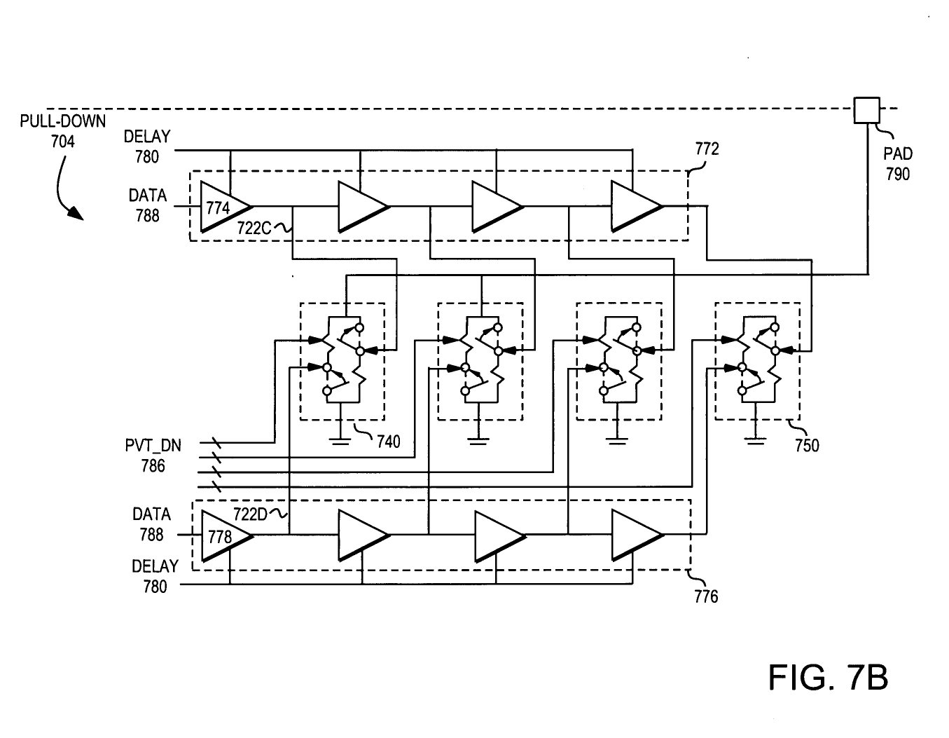

FIG. 7A illustrates one embodiment of a pull-up portion 702 of a driver circuit. Each of the selectable variable impedances 730 includes a fixed portion 732 and a variable portion 734. The pull-up portion includes a first delay line 716 for controlling the selection of the fixed portion 732 of each selectable variable impedance 730. The pull-up portion includes a second delay line 712 for controlling the selection of the variable portion 734 of each selectable variable impedance 730. The delay lines 712, 716 are matched such that each delay buffer 714 within a given delay line 712 contributes substantially the same delay to its received signal as does its corresponding delay buffer 718 within the other delay line 716. Thus delay line tap 722A and delay line 722B provide distinct versions of the data signal 782 having the same delay.

Data 782 may correspond directly to data 682 of FIG. 6. Alternatively, data 782 may correspond to a logical combination of data 682 with other signals (e.g., tri-state signal) such that data 782 is equivalent, for example to signal 683 of FIG. 6.

Delay control 780 is provided to the delay buffers within each delay line to control the amount of delay contributed by each delay buffer. The value of the variable portion of each selectable variable impedance is determined by PVT compensation signal PVT_UP 784.

FIG. 7B illustrates one embodiment of the corresponding pull-down portion 704 of the driver circuit. The pull-down portion similarly includes a first delay line 776 for controlling the selection of the fixed portion of each selectable variable impedance 750. The pull-down portion includes a second delay line 772 for controlling the selection of the variable portion of each selectable variable impedance 740. The delay lines 772, 776 are matched such that each delay buffer 774 within a given delay line 772 contributes substantially the same delay to its received signal as does its corresponding delay buffer 778 within the other delay line 776. Thus delay line tap 722C and delay line 722D provide distinct versions of the data signal 782 having the same delay.

Data 788 may correspond directly to data 682 of FIG. 6. In one embodiment, data 788 is the same as data 782 of FIG. 7A. Alternatively, data 788 may correspond to a logical combination of data 682 with other signals (e.g., tri-state signal) such that data 788 is equivalent, for example to signal 685 of FIG. 6.

Delay control 780 is provided to the delay buffers within each delay line to control the amount of delay contributed by each delay buffer. The value of the variable portion of each selectable variable impedance is determined by PVT compensation signal PVT_DN 786.

In one embodiment, the delay lines 772, 776 of the pull-down portion 704 are substantially the same as corresponding delay lines 712, 716 of the pull-up portion 702. Accordingly delay line taps 722A, 722B, 722C, and 722D are corresponding delayed versions of the data signal 782 with the same delay. Alternatively, if data 782 of FIG. 7A is not the same as data 788 of FIG. 7B, then 722C and 722D may be distinctly generated from logical combinations of data 782 with other logic signals. This permits a tri-state condition for example, where 722A, 722B have complementary values from 722C, and 722D such that none of the pull-up and pull-down selectable variable impedances is coupled to the output pad.

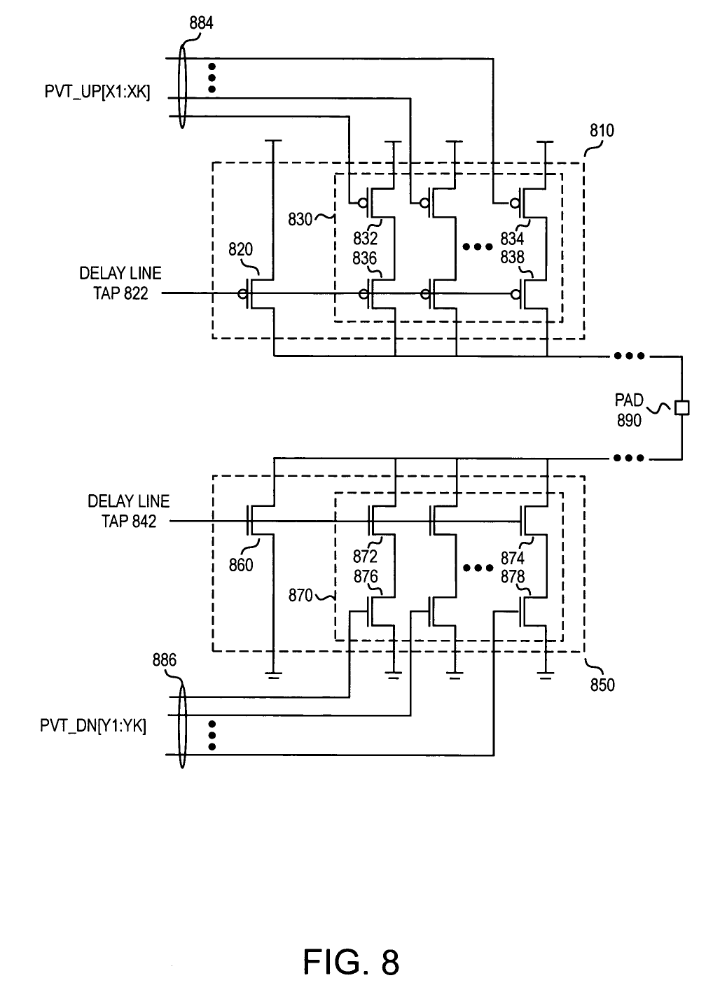

FIG. 8 illustrates one embodiment of a pull-up selectable variable impedance 810. A single delay line tap 822 selectively couples both the fixed portion 820 and variable portion 830 of the selectable variable impedance 810 to pad 890. Similarly, a single delay line tap 842 selectively couples both the fixed portion 860 and variable portion 870 of the pull-down selectable variable impedance 850 to pad 890. The pull-up and pull-down selectable variable impedances 810, 850 embodied in FIG. 8 are suitable for the selectable variable impedances 620, 640, respectively, of FIG. 6.

In one embodiment, delay line taps 822 and 842 represent the same delay line tap rather than delay line taps from distinct delay lines. In an alternative embodiment, delay line taps 822 and 842 are associated with delay line taps from distinct delay lines.

The variable portion 830 of pull-up selectable variable impedance 810 comprises a plurality (k) of series-coupled transistor pairs (e.g., 832, 836). Transistors 834-836 are selected in accordance with PVT compensation signal, PVT_UP[X₁:Xₖ] 884. Transistors 836-838 are selected in accordance with delay line tap 822. Given that all of the transistors 836-838 are selected whenever the fixed portion 820 is selected, the impedance contributed by the variable portion 830 is determined by PVT_UP[X₁:Xₖ]. In particular, whenever delay line tap 822 is asserted for the selection of selectable variable impedance 810, the number of series-coupled transistors that are selected is determined by PVT_UP[X₁:Xₖ].

When selected, each series-coupled transistor pair contributes impedance coupled in parallel with that contributed by the fixed impedance portion 820 and any other selected series-coupled transistor pairs. In one embodiment the impedance of any one of the series-coupled transistor pairs (e.g., 832, 836) is significantly greater than that of the fixed impedance 820.

The variable portion 870 of pull-down selectable variable impedance 850 comprises a plurality (k) of series-coupled transistor pairs (e.g., 872, 876). Transistors 872-874 are selected in accordance with PVT compensation signal, PVT_DN[Y₁:Yₖ] 886. Transistors 876-878 are selected in accordance with delay line tap 842. Given that all of the transistors 876-878 are selected whenever the fixed portion 860 is selected, the impedance contributed by the variable portion 870 is determined by PVT_DN[Y₁:Yₖ]. In particular, whenever delay line tap 842 is asserted for the selection of selectable variable impedance 870, the number of series-coupled transistors that are selected is determined by PVT_DN[Y₁:Yₖ].

When selected, each series-coupled transistor pair contributes impedance coupled in parallel with that contributed by the fixed impedance portion 860 and any other selected series-coupled transistor pairs. In one embodiment the impedance of any one of the series-coupled transistor pairs (e.g., 872, 876) is significantly greater than that of the fixed impedance 860.

In the illustrated embodiment, the pull-up selectable variable impedance transistors are p-type transistors. The pull-down selectable variable impedance transistors are n-type transistors. In one embodiment, the selectable impedance transistors are MOSFETs.

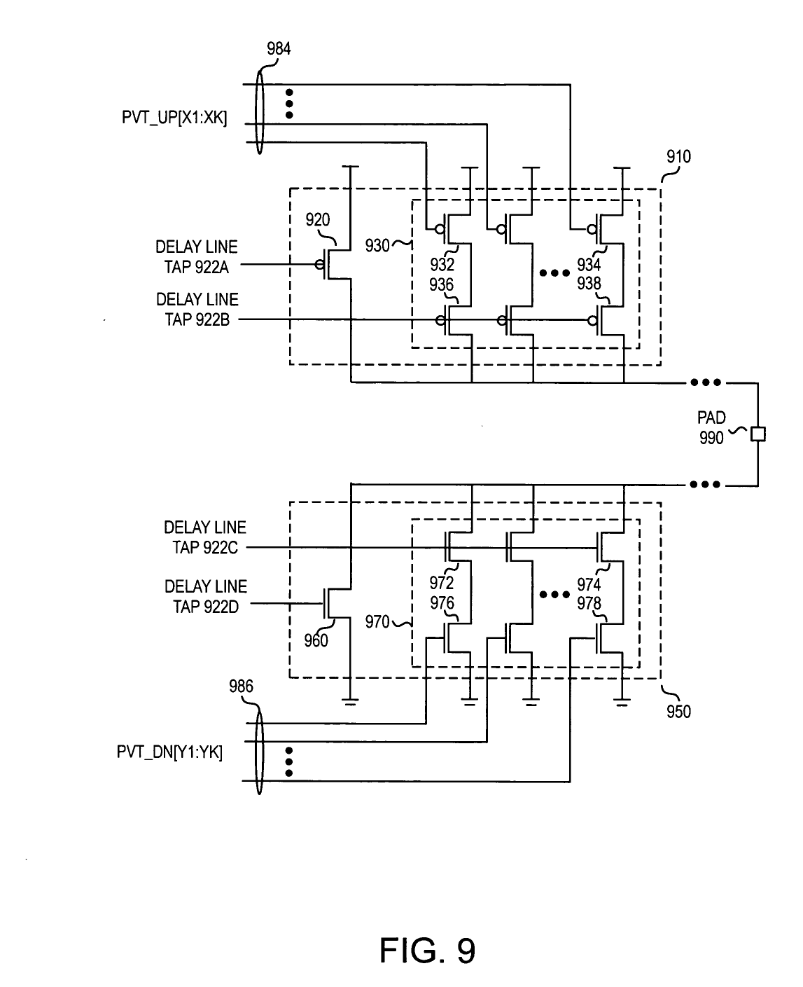

FIG. 9 illustrates alternative pull-up and pull-down selectable variable impedances suitable for the pull-up 702 and pull-down 704 portions of the output driver of FIGS. 7A and 7B. The architecture and function of the selectable variable impedances (910, 950) is identical to that discussed with respect to FIG. 8 with the exception that distinct delay line taps 922A, 922B are provided for selecting the fixed portion 920 and variable portion 930 of the pull-up selectable variable impedance 910. Similarly, distinct delay line taps 922C, 922D are provided for selecting the fixed portion 960 and variable portion 970 of the pull-down selectable variable impedance 950.

In one embodiment, delay line taps 922A, 922B are coupled to the same delay line tap rather than corresponding delay line taps from distinct delay lines. In an alternative embodiment, delay line taps 922A and 922B are associated with delay line taps from distinct delay lines. Similarly, delay line taps 922C, 922D are coupled to the same delay line tap rather than corresponding delay line taps from distinct delay lines. Alternatively, delay line taps 922C and 922D are associated with delay line taps from distinct delay lines. In one embodiment, delay line taps 922A, 922B, 922C, 922D are corresponding delayed versions of the same data signal, wherein the corresponding delay line taps have substantially the same delay.

In one embodiment, the pull-up PVT compensation signal is a j-bit thermometer coded signal comprising bits b₁, b₂, . . . bⱼ. Assume the lowest order bit has the value D. A thermometer coded signal has the property that if there is a bₘ such that bₘ≠D when proceeding from the lowest order bit b₁ to the highest order bit bⱼ′ then b₁ . . . bₘ₋₁=D, bₘ . . . bⱼ=\overline{D}. In one embodiment PVT_UP[X₁:Xⱼ] and PVT_DN[Y₁:Yⱼ] are complements of each other (e.g., PVT[Y1]=\overline{PVT[X₁]}) due to the complementary requirements for selecting n-channel and p-channel transistors.

The thermometer coded PVT compensation signal (pull-up or pull-down) is used to alter the output impedance of the output driver from a nominal amount to a PVT compensated amount. In one embodiment, the thermometer coded PVT signal is mapped to the variable impedance portions of the selectable impedance groups so that changes in the PVT compensation signal and therefore changes in the variable impedances are distributed substantially equally across the selectable variable impedances. Thus, for example, given n=4 and a state change in three adjacent bits of the thermometer code, only one selectable transistor in three of the four selectable variable impedances will change state (i.e., selected/de-selected) in contrast to changing the state of three transistors of a single selectable variable impedance. The PVT compensation signal is mapped to the selectable variable impedances to distribute adjacent bits of the thermometer code across multiple selectable variable impedances such that no adjacent thermometer code bits are mapped to the same selectable variable impedance.

With n selectable variable impedances each having k individually selectable impedances in the variable impedance portion, a PVT_UP thermometer coded signal of at least n×k bits is required, (i.e., PVT_UP[B₁:Bₘ], where m≧n×k). The mapping from PVT_UP[B₁:Bₘ] to PVT_UP[Xᵢ₁:Xᵢₖ] for each selectable transistor j of the variable impedance portion of selectable impedance group i is as follows: Xᵢⱼ=Bᵢ₊ₙ₍ⱼ₋₁₎ where iε{1 . . . n}, jε{1 . . . k}. The equation is based on a one-based rubric for the PVT_UP signal, the selectable impedance groups, and the variable impedances within each group. In one embodiment, PVT_UP and PVT_DN signals are complements such that PVT_DN[Bₗ:Bₘ]=\overline{PVT_UP[B₁:Bₘ]}.

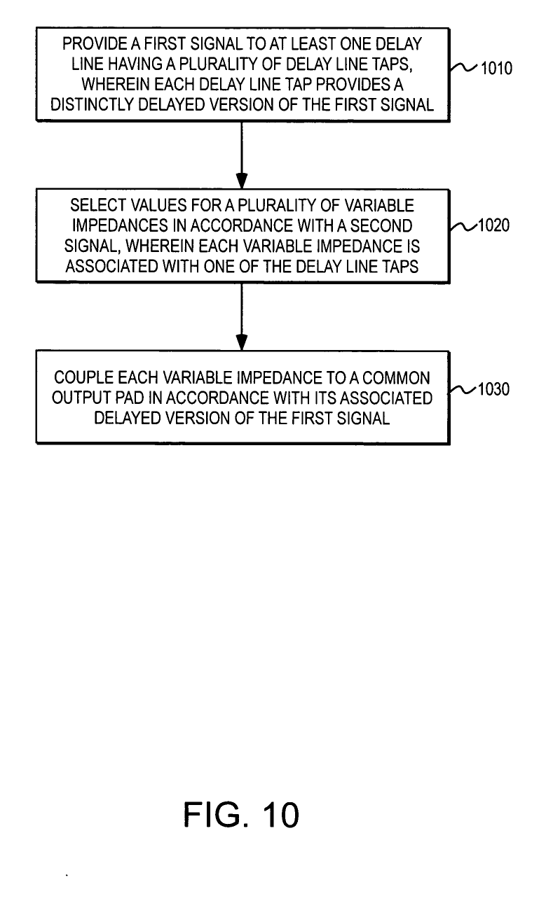

FIG. 10 illustrates one embodiment of a method for controlling slew. A first signal is provided to at least one delay line having a plurality of delay line taps in step 1010. Each delay line tap provides a distinctly delayed version of the first signal.

Values for a plurality of variable impedances are selected in accordance with a second signal in step 1020. Each variable impedance is associated with one of the delay line taps. In step 1030, each variable impedance is coupled to a common pad in accordance with its delayed version of the first signal.

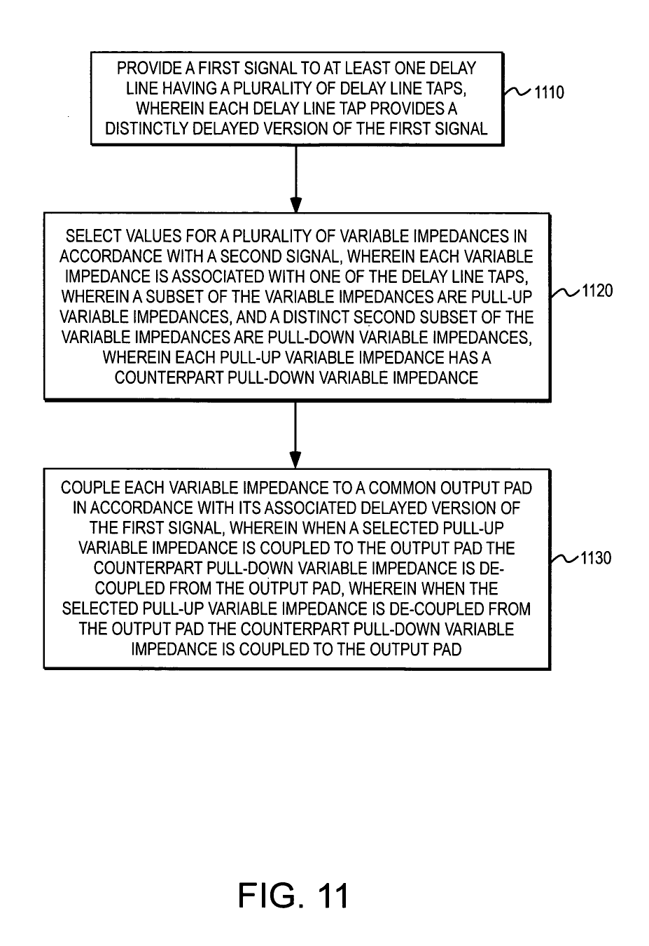

FIG. 11 illustrates one embodiment of a method for controlling skew specifically incorporating pull-up and pull-down portions. In step 1110 a first signal is provided to at least one delay line having a plurality of delay line taps. Each delay line tap provides a distinctly delay version of the first signal. The first signal may, for example, be a data signal to be driven onto an output pad.

In step 1120, values for a plurality of variable impedances are selected in accordance with a second signal. Each variable impedance is associated with one of the delay line taps A subset of the variable impedances are pull-up variable impedances and a distinct second subset of the variable impedances are pull-down variable impedances, wherein each pull-up variable impedance has a counterpart pull-down variable impedance.

In step 1130, each variable impedance is coupled to a common output pad in accordance with its associated delayed version of the first signal. When a selected pull-up variable impedance is coupled to the output pad, the counterpart pull-down variable impedance is de-coupled from the output pad. When a selected pull-up variable impedance is de-coupled from the output pad, the counterpart pull-down variable impedance is coupled from the output pad.

In one embodiment, the effective impedance of all selectable variable impedances coupled to the output pad is substantially the same as a bus impedance of any bus (e.g., 692) connected to the pad. Typically, such a bus impedance is in a range of 40Ω-50Ω with a nominal impedance of 45Ω.

Various modifications and changes may be made thereto without departing from the broader spirit and scope of the invention as set forth in the claims. The specification and drawings are, accordingly, to be regarded in an illustrative rather than a restrictive sense.

1. A method of controlling slew, comprising:
providing an output driver having a plurality of selectable variable impedances; and
successively coupling each selectable variable impedance to a pad of the output driver in response to initiation of a first signal transition to monotonically vary a an output driver source impedance throughout the signal transition.

2. The method of claim 1, further comprising:
providing the first signal to a tapped delay line, each delay line tap providing a delayed version of the first signal, wherein the selectable variable impedances are successively coupled to the pad in accordance with the delayed versions of the first signal.

3. The method of claim 2 wherein the output driver source impedance is varied in a plurality (n) of steps.

4. The method of claim 3 wherein each selectively coupled variable impedance has substantially a same impedance value.

5. The method of claim 3 wherein at least one selectively coupled variable impedance has a substantially distinct impedance value from that of any other selectable variable impedance.

6. The method of claim 3 wherein a process/voltage/temperature (PVT) signal controls an impedance value of each of the selected variable impedances.

7. The method of claim 1 wherein the output driver source impedance varies from an initial impedance to a final impedance wherein the final impedance substantially matches a bus impedance of a bus coupled to the pad of the output driver.

8. The method of claim 7 wherein the final impedance is in a range of approximately 40Ω-50Q.

9. A method of controlling slew, comprising:
providing a first signal to at least one delay line having a plurality of delay line taps, wherein each delay line tap provides a distinctly delayed version of the first signal;
selecting an impedance value for each of a plurality of selectable variable impedances in accordance with a second signal, wherein each selectable variable impedance is associated with one of the distinctly delayed versions of the first signal; and
selectively coupling each selectable variable impedance to a common output pad in accordance with its associated delayed version of the first signal to vary an output driver source impedance of an output driver associated with the pad.

10. The method of claim 9 wherein the second signal is a process/voltage/temperature (PVT) compensation signal.

11. The method of claim 10 wherein the PVT compensation signal is thermometer coded.

12. The method of claim 9 wherein each selectable variable impedance has a discretely variable impedance value.

13. The method of claim 9 wherein the output driver source impedance is varied in a plurality (n) of steps.

14. The method of claim 9 wherein the impedance value of each of the selectable variable impedances is substantially the same.

15. The method of claim 9 wherein the impedance value of at least one of the selectable variable impedances is distinct from that of any other selectable variable impedance.

16. The method of claim 9 wherein the output driver source impedance varies from an initial impedance to a final impedance wherein the final impedance substantially matches a bus impedance of a bus coupled to the output driver.

17. The method of claim 16 wherein the bus impedance is in a range of approximately 40Ω-50Ω.

18. An output driver apparatus, comprising:
at least one delay line providing a plurality of delay line taps, each tap providing a delayed version of any first signal received by the delay line; and
a pull-up portion comprising a first plurality of selectable variable impedances, each selectable variable impedance of the first plurality selectively coupled to a common output pad in accordance with an associated one of the delayed versions of the first signal.

19. The apparatus of claim 18 wherein a value of each selectable variable impedance is determined by a second signal.

20. The apparatus of claim 19 wherein the second signal is a process/voltage/temperature (PVT) compensation signal.

21. The apparatus of claim 20 wherein the PVT compensation signal is thermometer coded.

22. The apparatus of claim 21 wherein the PVT compensation signal is mapped to the selectable variable impedances to distribute adjacent bits of the thermometer code across multiple selectable variable impedances.

23. The apparatus of claim 18, further comprising:
a pull-down portion comprising a second plurality of selectable variable impedances each associated with the delayed version of the first signal, each selectable variable impedance of the second plurality corresponding to one selectable variable impedance of the first plurality, wherein each selectable variable impedance of the second plurality is selectively coupled to the common output pad in accordance with the associated delayed version of the first signal.
